(19) United States
(12) Patent Application Publication
(10) Pub. No.: US 2012/0171873 A1
(43) Pub. Date: Jul. 5, 2012

(54) THIN FILM TRANSISTOR PRINTING APPARATUS AND THIN FILM TRANSISTOR PRINTING METHOD USING THE SAME

(75) Inventors: Jae-woo Chung, Yongin-si (KR); Young-ki Hong, Anyang-si (KR)

(73) Assignee: SAMSUNG ELECTRONICS CO., LTD., Suwon-si (KR)

(21) Appl. No.: 13/179,967

(22) Filed: Jul. 11, 2011

(30) Foreign Application Priority Data
Jan. 5, 2011 (KR) 1020110001089

(51) Int. Cl. H01L 21/30; B05C 5/00

(52) U.S. Cl. 438/758; 118/300; 118/323; 257/E21.211

(57) ABSTRACT

According to an example embodiment, a thin film transistor (TFT) printing apparatus includes a stage having a TFT substrate loaded thereon, a stage moving device configured to move the stage according to a printing vector set to correspond to a print pattern, and a print head on an upper side of the stage and including a plurality of nozzles in a matrix shape.

### CROSS-REFERENCE TO RELATED APPLICATIONS

This application claims priority under 35 U.S.C. §119 to Korean Patent Application No. 10-2011-0001089, filed on Jan. 5, 2011, in the Korean Intellectual Property Office, the disclosure of which is incorporated herein in its entirety by reference.

### BACKGROUND

1. Field

Example embodiments relate to thin film transistor (TFT) printing apparatuses and/or TFT printing methods using the TFT printing apparatuses.

2. Description of the Related Art

Generally, a thin film transistor (TFT) is used as a switching device for driving a display unit in a display. The TFT includes a gate line that transfers scan signals for controlling the TFT and a data line that transfers signals that are to be applied to a pixel electrode.

Currently, a photolithography technology is mainly utilized to form gate lines and data lines included in TFTs as fine-width lines.

However, when there is a process of depositing a metal material to be used as a wire or an electrode in a photolithography process, due to batch process characteristics and high process temperature, increase of productivity and formation of a next-generation flexible display using a plastic substrate requiring a low temperature process are restricted, and realization of a large area display is difficult.

Due to such problems, a printing technology is used instead of the photolithography technology.

Among a variety of printing methods, an inkjet printing method, in which a substrate is not contacted, is being evaluated as a major technological innovation. Much research into the inkjet printing method has been globally conducted.

When a multilayer device such as a TFT uses a contact printing method, a structure of a lower layer deforms due to contamination of heterogeneous materials of interlayers and a printing pressure. Thus, a non-contact inkjet printing method may be desirable. Increases in printing speed and printing quality may be important in manufacturing a printing device using the non-contact inkjet printing method.

A conventional inkjet printing method of forming lines included in a TFT uses a raster scan method in which a bitmap pattern is used. For example, lines are formed by ejecting ink from nozzles according to a bitmap pattern while operating a substrate stage on which a substrate is loaded in a Y direction (operation 1), transferring a print head in an X direction by a raster size (dx) and operating the substrate stage to an initial position (y=0) (operation 2), and repeating operations 1 and 2.

However, when widths of lines that are to be printed have a reduced pixel unit size, the number of pixels and the number of times the substrate stage is operated is increased, which increases a total printing time. For example, if a pitch Px of a pixel in an X direction is 150 μm, a pitch Py of a pixel in a Y direction is 450 μm, the raster size(dx) is 5 μm, the number of times the substrate stage is conveyed is (Px/dx=150/5=30), a operating distance for one pixel is 27000 μm (450×2×30=27000 μm), and a real inkjetting distance is 750 μm, an inkjetting ratio is (750/27000)*100=2.8%.

As described above, the inkjet printing distance ratio of the conventional printing method is 2.8%. Thus, a distance ratio for operating a print head is 97.2%, which means that a time for operating the print head is 97.2% of the total time for printing. Therefore, throughput for line printing per time unit is reduced.

### SUMMARY

According to an example embodiment, a thin film transistor (TFT) printing apparatus includes a stage having a TFT substrate loaded thereon, a stage moving device configured to move the stage according to a printing vector set to correspond to a print pattern, and a print head on an upper side of the stage and including a plurality of nozzles in a matrix shape.

According to an example embodiment, the stage moving device includes a main scan direction stage moving unit configured to move the stage in a main scan direction and a sub-scan direction stage moving unit configured to move the stage in a sub-scan direction. The main scan direction stage moving unit and the sub-scan direction stage moving unit are further configured to simultaneously move the stage in a vector direction.

According to an example embodiment, the TFT printing apparatus further includes a print head moving device configured to move the print head according to the printing vector set.

According to an example embodiment, the print head moving device includes a main scan direction print head moving unit configured to move the print head in the main scan direction and a sub-scan direction print head moving unit configured to move the print head in the sub-scan direction. The main scan direction print head moving unit and the sub-scan direction print head moving unit are further configured to simultaneously move the print head in a vector direction.

According to an example embodiment, the print head moving device is further configured to move slower than the stage moving device.

According to an example embodiment, the plurality of nozzles of the print head correspond to pixels on which printing operations are to be performed.

According to an example embodiment, the plurality of nozzles are arranged by a multiple pitch gap.

According to an example embodiment, a TFT printing method includes generating a printing vector that sets a print path by using a vector corresponding to a print pattern, and printing the print pattern by using a print head according to the printing vector.

According to an example embodiment, the TFT printing further includes printing the print pattern in print regions of the printing vector by operating the print head in printing sections corresponding to a plurality of nozzles of the print head, and moving the print head in movement regions of the printing vector so that the print head is moved to an adjacent print region without printing the print pattern.

According to an example embodiment, the TFT printing method further includes performing print operations on pixels that correspond to the plurality of nozzles of the print head.

According to an example embodiment, the TFT printing method further includes moving the print head in a moving region to a next print region.

According to an example embodiment, the TFT printing method further includes arranging a plurality of nozzles according to an integer multiple of a pitch gap on the print head.

According to an example embodiment, the TFT printing method further includes moving a stage moving device to move the print head relative to the stage moving device.

According to an example embodiment, the TFT printing method further includes moving the print head in the print regions using a print head moving device and moving the print head in the movement regions using a stage moving device. The print head moving device includes a main scan direction print head moving unit configured to move the print head in a main scan direction and a sub-scan direction print head moving unit configured to move the print head in a sub-scan direction.

According to an example embodiment, the TFT printing method further includes moving the print head moving device slower than the stage moving device.

### BRIEF DESCRIPTION OF THE DRAWINGS

The above and other features and advantages will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a perspective view of a thin film transistor (TFT) printing apparatus, according to an example embodiment;

FIG. 2 is a perspective view of a TFT printing apparatus, according to another example embodiment;

FIG. 3 is a view for explaining a TFT printing method using the TFT printing apparatus of FIG. 1, according to an example embodiment;

FIG. 4 is a view of a printing vector according to the TFT printing method of FIG. 3;

FIG. 5 is a view for explaining a TFT printing method using the TFT printing apparatus of FIG. 1, according to another example embodiment;

FIG. 6 is a view of a printing vector according to the TFT printing method of FIG. 5; and

FIG. 7 is a graph of a variation of a line width of a print pattern with respect to printing time.

### DETAILED DESCRIPTION

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/ acts involved.

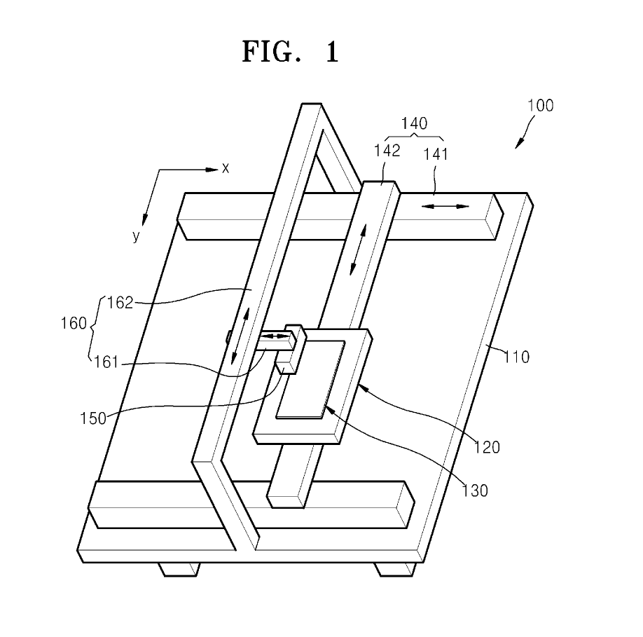

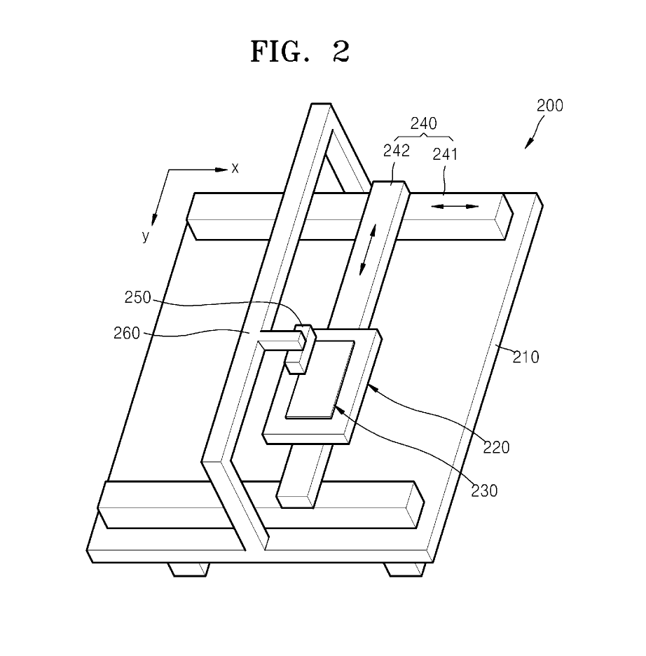

FIG. 1 is a perspective view of a thin film transistor (TFT) printing apparatus 100, according to an example embodiment. FIG. 2 is a perspective view of a TFT printing apparatus 200, according to another example embodiment.

Referring to FIG. 1, the TFT printing apparatus 100 includes a base 110, a stage 120 on which a TFT substrate 130 is loaded, a stage moving device 140 that moves the stage 120 in a main scan direction and in a sub-scan direction, a print head 150 that performs a desired printing operation on the TFT substrate 130, and a print head moving device 160 that moves the print head 150 in the main scan direction and in the sub-scan direction. In this regard, for description convenience, the main scan direction and the sub-scan direction are an X-axial direction and a Y-axial direction, respectively.

The stage moving device 140 includes a main scan direction stage moving unit 141 that moves the stage 120 in the main scan direction and a sub-scan direction stage moving unit 142 that moves the stage 120 in the sub-scan direction. The stage 120 may be moved in a vector direction by simultaneously moving the main scan direction stage moving unit 141 and the sub-scan direction stage moving unit 142.

The print head moving device 160 includes a main scan direction print head moving unit 161 that moves the print head 150 in the main scan direction and a sub-scan direction print head moving unit 162 that moves the print head 150 in the sub-scan direction. The print head 150 may be moved in a vector direction by simultaneously moving the main scan direction print head moving unit 161 and the sub-scan direction print head moving unit 162.

In this regard, for description convenience, a vector direction is determined by using a definition of a vector. For example, if the stage 120 is simultaneously moved in the X-axial direction and in the Y-axial direction by a predetermined or desired distance, the stage 120 moves from a start point to an end point in a rectilinear manner. That is, a vector direction is a direction corresponding to a diagonal movement distance of a plane formed by an X-axial movement distance and a Y-axial movement distance. This also applies to a movement of the print head 150.

A speed of moving the stage moving device 140 is faster than that of moving the print head moving device 160. That is, the speed of moving the stage 120 by using the stage moving device 140 is faster than that of moving the print head 150 by using the print head moving device 160. Thus, the stage moving device 140 may be used to move the TFT substrate 130 to a desired position relatively quickly, and the print head moving device 160 may be used to precisely move the print head 150 and eject ink.

The print head 150 may include a plurality of nozzles for ejecting ink. The nozzles may be disposed in a matrix shape. Gaps between neighboring nozzles may be one pitch, or may be a multiple of one pitch as occasion demands, for example, two times, three times, . . . n times. This will be described in more detail with reference to a TFT printing method below.

The print head 150 is not limited to any method of ejecting ink and may use an inkjet printing method such as a piezo method, a thermal driving method, an electrostatic method, etc. Such an inkjet printing method has the following characteristics. First, as a non-contact printing method, a pattern may be formed without deforming a lower layer when layers of a multilayer device such as a TFT are deposited. Second, a pattern width may be changed by adjusting ink droplets ejected from an inkjet nozzle, and a printing shape is freely formed by forming various patterns (such as lines and points). Third, several micrometer line widths required by the TFT may be realized if droplets below picoliter are formed. Fourth, no expensive device is required compared to a method of forming the TFT by using photolithography and deposition, processes may be dramatically simplified, and manufacturing cost may be reduced due to limited consumption of materials. Fifth, a substrate is not restricted to any one type.

Referring to FIG. 2, the TFT printing apparatus 200 according to an example embodiment includes a base 210, a stage 220 on which a TFT substrate 230 is loaded, a stage moving device 240 that moves the stage 220 in a main scan direction and in a sub-scan direction, a print head 250 that performs a desired printing operation on the TFT substrate 230, and a print head fixing device 260 that supports the print head 250.

The stage moving device 240 includes a main scan direction stage moving unit 241 that moves the stage 220 in the main scan direction and a sub-scan direction stage moving unit 242 that moves the stage 220 in the sub-scan direction. The stage 220 may be moved in a vector direction by simultaneously moving the main scan direction stage moving unit 241 and the sub-scan direction stage moving unit 242.

The TFT printing apparatus 200 of FIG. 2 is different from the TFT printing apparatus 100 of FIG. 1 in that the TFT printing apparatus 200 of FIG. 2 does not include a print head moving device. That is, the print head 250 is fixed to the print head fixing device 260. Thus, the TFT substrate 220 is moved by using the stage moving device 240, so that the TFT substrate is moved relative to the print head 250 to correspond the print head 250 to a desired position on the TFT substrate. The description of the TFT printing apparatus 200 is the same as that of the TFT printing apparatus 100 described with reference to FIG. 1.

A TFT printing method using a TFT printing apparatus will now be described below.

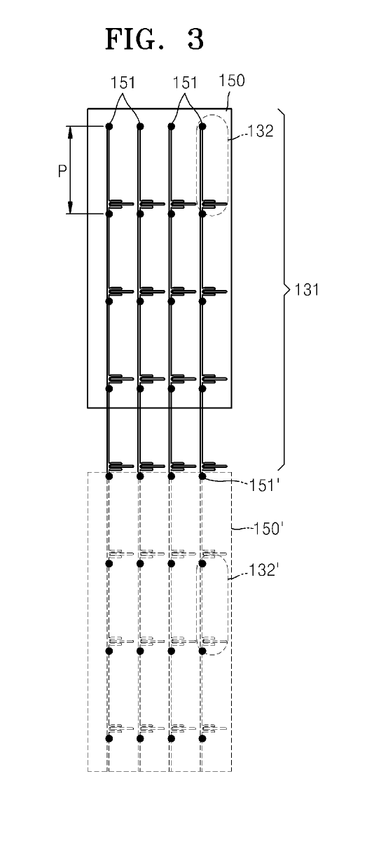

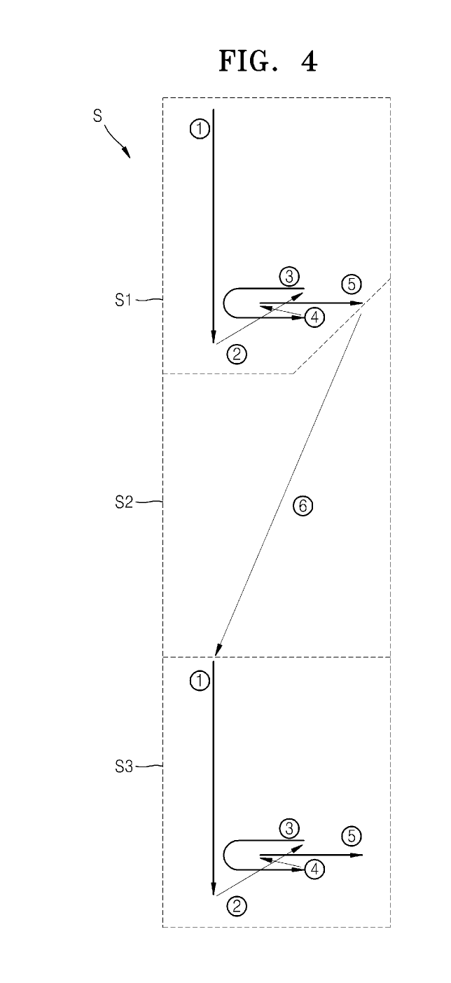

FIG. 3 is a view for explaining a TFT printing method using the TFT printing apparatus 100 of FIG. 1, according to an example embodiment. FIG. 4 is a view of a printing vector S according to the TFT printing method of FIG. 3.

Referring to FIG. 3, a desired array print pattern 131 of a TFT is printed on the TFT substrate 130. The array print pattern 131 of the TFT is a repetition of unit print patterns 132 each having the same shape. The array print pattern 131 of the TFT has the following characteristics. First, the array print pattern 131 is repeated having a pitch in X and Y directions. Second, a solid pattern occupies a very small portion of a total area of the array print pattern 131. Third, the number of pixels per unit area increases as resolution of a display is increased, sizes of pixels are reduced, and wirings and electrode line widths are reduced for improvement of an aperture rate.

A single unit print pattern 132 corresponds to a single pixel (not shown). A plurality of nozzles 151 are arranged on the print head 150 in an array shape and each corresponds to a pixel (not shown). Thus, each nozzle 151 prints one single unit print pattern 132. The nozzles 151 are spaced apart from each other by a pitch P.

The nozzles 151 of the print head 150 in a region indicated by a solid line perform printing operations to print the corresponding unit print patterns 132, and then move to an adjacent region to become nozzles 151′ of a print head 150′ in a region indicated by a dotted line to print unit print patterns 132′. That is, the print head 150 prints a region, moves to an adjacent region, and then repeats the same printing operation to print the array print pattern 131.

Referring to FIG. 4, the printing vector S is a movement path of the print head 150 that the print head follows to print the array print pattern 131. In more detail, the printing vector S is a movement path of a nozzle, and thus a movement of the nozzle is a movement of the print head 150.

The printing vector S includes print regions Si and S3 in which the unit print patterns 132 are printed and includes a movement region S2 in which the print head 150 is moved from the print region Si to the print region S3 without performing a printing operation.

In the print regions S1 and S3, the print head 150 moves according to a determined or defined path (\textcircled{1}→\textcircled{5}) and prints the unit print patterns 132. In this regard, the print head 150 moves in the print region S1 by using the print head moving device 160. Paths other than a horizontal or vertical path, such as inclined paths (\textcircled{2} and \textcircled{4}) or a curved path (a middle path of \textcircled{3}), are sections where the print head 150 moves in a vector direction as described above.

In the movement region S2 (a path \textcircled{6}), the print head 150 of FIG. 3 in the region indicated by a solid line moves to become the print head 150′ in the region indicated by a dotted line. In the movement region S2, the print head 150 moves in a vector direction by using the stage moving device 140. The speed of the stage moving device 140, which moves the stage 130, is greater than that of the print head moving device 160, which moves the print head 150, and thus moving the stage 130 is faster than moving the print head 150.

A desired print pattern array may be printed on a TFT substrate by repeating printing according to the printing vector S.

Table 1 below shows values of the printing vectors of FIG. 4.

TABLE 1

| | | | MOVEMENT | MOVEMENT | OPERATION |
|---|---|---|---|---|---|
| | | SUB- | DISTANCE IN MAIN | DISTANCE IN SUB- | OF PRINT |
| REGION | STEP | STEP | SCAN DIRECTION | SCAN DIRECTION | HEAD |
| S1 | 0 | 00 | 0 | 0 | Off |
| | 1 | 10 | 0 | 450 | On |
| | 2 | 20 | 100 | −75 | Off |
| | 3 | 30 | −100 | 0 | On |
| | 3 | 31 | 0 | 50 | On |
| | 3 | 32 | 100 | 0 | On |
| | 4 | 40 | −50 | −25 | Off |
| | 5 | 50 | 75 | 0 | On |
| S2 | 6 | 60 | −125 | 1400 | Off |
| S3 | 1 | 10 | 0 | 450 | On |
| | 2 | 20 | 100 | −75 | Off |
| | 3 | 30 | −100 | 0 | On |
| | 3 | 31 | 0 | 50 | On |
| | 3 | 32 | 100 | 0 | On |
| | 4 | 40 | −50 | −25 | Off |
| | 5 | 50 | 75 | 0 | On |
| | 6 | 60 | −125 | 50 | Off |

In Table 1 above, − denotes a negative direction

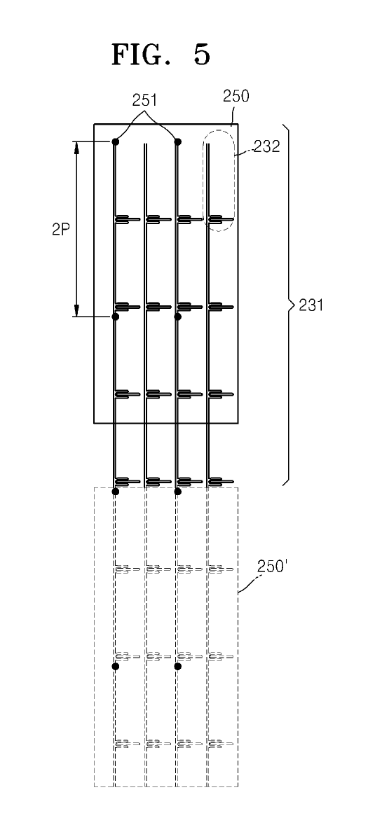

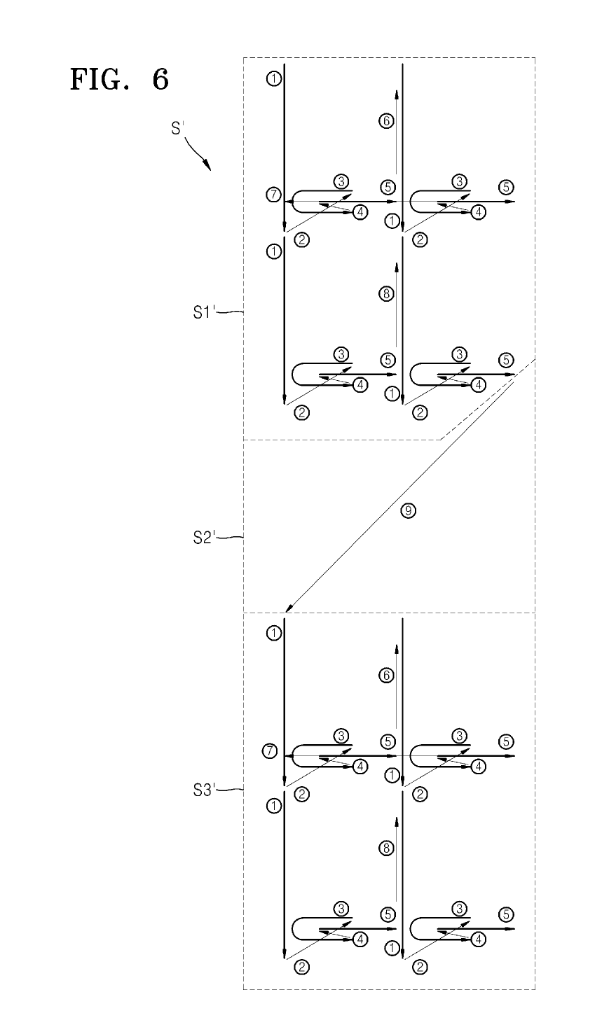

FIG. 5 is a view for explaining a TFT printing method using the TFT printing apparatus 100 of FIG. 1, according to another example embodiment. FIG. 6 is a view of a printing vector S′ according to the TFT printing method of FIG. 5.

Referring to FIGS. 5 and 6, an array print pattern 231 and unit print patterns 232 included in the array print pattern 231 are the same as those shown in FIG. 3. However, nozzles 251 of a print head 250 are spaced apart from each other by 2 pitches P. Thus, the printing vector S′ is generated to print the unit print patterns 232 in four pixels adjacent to one nozzle.

The printing vector S′ includes print regions S1' and S3′ in which the unit print patterns 232 are printed and includes a movement region S2′ in which the print head 250 is moved from the print region S1′ to the print region S3′ without performing a printing operation.

In the print regions S1′ and S3′, the print head 250 moves according to a determined/defined path (\textcircled{1}→\textcircled{5}) and prints the unit print patterns 232. An operation of printing the unit print patterns 232 is the same as described with reference to the print region S1 shown in FIG. 4. In paths (\textcircled{6}, \textcircled{7}, and \textcircled{8}) where the print head 250 moves from one unit print pattern to an adjacent unit print pattern, the print head 250 moves but does not perform a printing operation. The print head 250 moves in the print region S1 by using the print head moving device 260 in the same manner as shown in FIG. 4. Paths other than a horizontal or vertical path, such as inclined paths (\textcircled{2} and \textcircled{4}) or a curved path (a middle path of \textcircled{3}), are sections where the print head 250 moves in a vector direction as described above.

In the movement region S2′ (a path \textcircled{9}), the print head 250 of FIG. 5 in a region indicated by a solid line, moves to become a print head 250′ in a region indicated by a dotted line. In the movement region S2′, the print head 250 moves in a vector direction by using the stage moving device 240.

A desired print pattern array may be printed on a TFT substrate by repeating printing according to the printing vector S′.

Meanwhile, when the print head 250 is fixed as shown in FIG. 2, the constructions described with reference to FIGS. 3 through 6 apply. However, only a stage moving device is moved to move the TFT substrate relative to the print head 250.

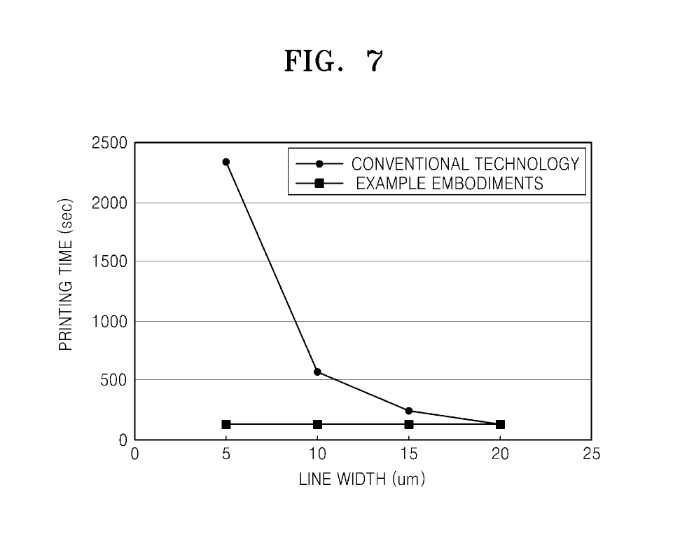

FIG. 7 is a graph of a variation of a line width of a print pattern with respect printing time.

Referring to FIG. 7, printing time in a conventional technology (a head raster scan method) increases geometrically according to a reduction of a line width, whereas in the example embodiments, there is no printing time variation when a line width is changed. If a line width of a print pattern is 5 μm, a printing time is reduced to ⅕ compared to the conventional technology.

Since a line width of an LCD is reduced (about 3 μm) so as to obtain a desire pixel aperture ratio, a printing time is further reduced according to the example embodiments compared to the conventional technology.

Although TFT printing methods, according to example embodiments, are described above, example embodiments are not limited thereto, and any printing method including a print pattern in which unit print patterns are repeated like in a TFT may be used.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A thin film transistor (TFT) printing apparatus, comprising:
a stage having a TFT substrate loaded thereon;
a stage moving device configured to move the stage according to a printing vector set to correspond to a print pattern; and
a print head on an upper side of the stage and including a plurality of nozzles in a matrix shape.

2. The TFT printing apparatus of claim 1, wherein the stage moving device comprises:
a main scan direction stage moving unit configured to move the stage in a main scan direction and a sub-scan direction stage moving unit configured to move the stage in a sub-scan direction,
wherein the main scan direction stage moving unit and the sub-scan direction stage moving unit are further configured to simultaneously move the stage in a vector direction.

3. The TFT printing apparatus of claim 2, further comprising:
a print head moving device configured to move the print head according to the printing vector set.

4. The TFT printing apparatus of claim 3, wherein the print head moving device comprises:
a main scan direction print head moving unit configured to move the print head in the main scan direction and a sub-scan direction print head moving unit configured to move the print head in the sub-scan direction,
wherein the main scan direction print head moving unit and the sub-scan direction print head moving unit are further configured to simultaneously move the print head in a vector direction.

5. The TFT printing apparatus of claim 3, wherein the print head moving device is further configured to move slower than the stage moving device.

6. The TFT printing apparatus of claim 1, wherein the plurality of nozzles of the print head correspond to pixels on which printing operations are to be performed.

7. The TFT printing apparatus of claim 6, wherein the plurality of nozzles are arranged by a multiple pitch gap.

8. A TFT printing method, comprising:
generating a printing vector that sets a print path by using a vector corresponding to a print pattern; and
printing the print pattern by using a print head according to the printing vector.

9. The TFT printing method of claim 8, further comprising:
printing the print pattern in print regions of the printing vector by operating the print head in printing sections corresponding to a plurality of nozzles of the print head; and
moving the print head in movement regions of the printing vector so that the print head is moved to an adjacent print region without printing the print pattern.

10. The TFT printing method of claim 9, further comprising:
performing print operations on pixels that correspond to the plurality of nozzles of the print head.

11. The TFT printing method of claim 8, further comprising:
moving the print head in a moving region to a next print region.

12. The TFT printing method of claim 11, further comprising:
arranging a plurality of nozzles according to an integer multiple of a pitch gap on the print head.

13. The TFT printing method of claim 9, further comprising:
moving a stage moving device to move the print head relative to the stage moving device.

14. The TFT printing method of claim 9, further comprising:
moving the print head in the print regions using a print head moving device and moving the print head in the movement regions using a stage moving device, wherein the print head moving device includes,
a main scan direction print head moving unit configured to move the print head in a main scan direction and a sub-scan direction print head moving unit configured to move the print head in a sub-scan direction.

15. The TFT printing method of claim 14, further comprising:
moving the print head moving device slower than the stage moving device.
